(19) United States
(12) Patent Application Publication
(10) Pub. No.: US 2024/0321342 A1
(43) Pub. Date: Sep. 26, 2024

(54) MEMORY DEVICE USING SEMICONDUCTOR ELEMENT

(71) Applicant: Unisantis Electronics Singapore Pte. Ltd., Singapore (SG)

(72) Inventors: Masakazu KAKUMU, Tokyo (JP); Koji Sakui, Tokyo (JP); Nozomu Harada, Tokyo (JP)

(21) Appl. No.: 18/609,167

(22) Filed: Mar. 19, 2024

(30) Foreign Application Priority Data
Mar. 24, 2023 (WO) PCT/JP2023/011810

(51) Int. Cl. G11C 11/4096; H01L 23/528; H10B 12/00

(52) U.S. Cl. CPC G11C 11/4096; H01L 23/5283; H10B 12/20

(57) ABSTRACT

A memory device includes a first n-layer formed on a first p-layer on a substrate; a second n-layer extending vertically with a second p-layer placed thereon; a first insulating layer partially covering the n-layers; a first gate insulating layer in contact with the first insulating layer; a first gate conductor layer in contact with the gate insulating layer and first insulating layer; a second insulating layer in contact with the first gate conductor layer; and a MOSFET formed of a third p-layer placed on the second p-layer, a second gate insulating layer placed atop the third p-layer, n+ layers placed on opposite ends of the third p-layer, and a second gate conductor layer. Contact area between the second p-layer and second n-layer is smaller than a cross-section of the second p-layer. A write/erase operation is performed by applying voltages to the n+ layers, gate conductor layers, and first n-layer.

### CROSS-REFERENCE TO RELATED APPLICATIONS

This application claims priority to PCT/JP2023/011810, filed Mar. 24, 2023, the entire content of which is incorporated herein by reference.

### BACKGROUND OF THE INVENTION

### Field of the Invention

The present invention relates to a memory device using a semiconductor element.

### Description of the Related Art

In recent years, in LSI (large scale integration) technology development, there have been demands for greater packaging density, higher performance, lower power consumption, and higher functionality of memory devices using semiconductor elements.

With a typical planar MOS transistor, a channel extends in a horizontal direction along an upper surface of a semiconductor substrate. In contrast, a channel of an SGT extends in a direction perpendicular to an upper surface of a semiconductor substrate (see, for example, Japanese Patent Laid-Open No. 2-188966 and Hiroshi Takato, Kazumasa Sunouchi, Naoko Okabe, Akihiro Nitayama, Katsuhiko Hieda, Fumio Horiguchi, and Fujio Masuoka: IEEE Transaction on Electron Devices, Vol. 38, No. 3, pp. 573-578 (1991)). Consequently, the SGT enables greater packaging density of semiconductor devices than does the planar MOS transistor. The use of the SGT as a select transistor enables high integration of a DRAM (dynamic random access memory; see, for example, H. Chung, H. Kim, H. Kim, K. Kim, S. Kim, K. W. Song, J. Kim, Y. C. Oh, Y. Hwang, H. Hong, G. Jin, and C. Chung: “4F2 DRAM Cell with Vertical Pillar Transistor (VPT),” 2011 Proceeding of the European Solid-State Device Research Conference, (2011)) connected with a capacitor, a PCM (phase change memory; see, for example, H. S. Philip Wong, S. Raoux, S. Kim, Jiale Liang, J. R. Reifenberg, B. Rajendran, M. Asheghi and K. E. Goodson: “Phase Change Memory,” Proceeding of IEEE, Vol. 98, No 12, December, pp. 2201-2227 (2010)) connected with a variable resistance element, an RRAM (resistive random access memory; see, for example, K. Tsunoda, K. Kinoshita, H. Noshiro, Y. Yamazaki, T. Iizuka, Y. Ito, A. Takahashi, A. Okano, Y. Sato, T. Fukano, M. Aoki, and Y. Sugiyama: “Low Power and high Speed Switching of Ti-doped NiO ReRAM under the Unipolar Voltage Source of less than 3V,” IEDM (2007)), and an MRAM (magneto-resistive random access memory; see, for example, W. Kang, L. Zhang, J. Klein, Y. Zhang, D. Ravelosona, and W. Zhao: “Reconfigurable Codesign of STT-MRAM Under Process Variations in Deeply Scaled Technology,” IEEE Transaction on Electron Devices, pp. 1-9(2015)) that varies resistance by changing an orientation of a magnetic spin using a current.

There is also a capacitorless DRAM memory cell made up of a single MOS transistor (see M. G. Ertosun, K. Lim, C. Park, J. Oh, P. Kirsch, and K. C. Saraswat: “Novel Capacitorless Single-Transistor Charge-Trap DRAM (1T CT DRAM) Utilizing Electron,” IEEE Electron Device Letter, Vol. 31, No. 5, pp. 405-407 (2010); J. Wan, L. Rojer, A. Zaslavsky, and S. Critoloveanu: “A Compact Capacitor-Less High-Speed DRAM Using Field Effect-Controlled Charge Regeneration,” Electron Device Letters, Vol. 35, No. 2, pp. 179-181 (2012); Takashi Ohasawa and Takeshi Hamamoto, “Floating Body Cell—a Novel Body Capacitorless DRAM Cell”, Pan Stanford Publishing (2011); T. Shino, N. Kusunoki, T. Higashi, T. Ohsawa, K. Fujita, K. Hatsuda, N. Ikumi, F. Matsuoka, Y. Kajitani, R. Fukuda, Y. Watanabe, Y. Minami, A. Sakamoto, J. Nishimura, H. Nakajima, M. Morikado, K. Inoh, T. Hamamoto, A. Nitayama: “Floating Body RAM Technology and its Scalability to 32 nm Node and Beyond,” IEEE IEDM (2006); and E. Yoshida: “A Capacitorless 1T-DRAM Technology Using Gate-Induced Drain-Leakage (GIDL) Current for Low-Power and High-Speed Embedded Memory,” IEEE IEDM (2006)). For example, out of positive hole groups and electron groups generated in a channel by impact ionization phenomenon using a source-drain current of an n-channel MOS transistor, with some or all of the positive hole groups being held in the channel, logical storage data of “1” is written. Then the positive hole groups are removed from the channel and logical storage data of “0” is written. Challenges for the memory cell are to correct reductions in an operating margin caused by fluctuations in a floating body channel voltage and correct reductions in data retention characteristics through removal of some positive hole groups, which are a signal charge accumulated in the channel.

There is also a twin-transistor MOS transistor memory element obtained by forming one memory cell on an SOI layer using two MOS transistors (see, for example, US2008/0137394 A1, US2003/0111681 A1, and F. Morishita, H. Noda, I. Hayashi, T. Gyohten, M. Oksmoto, T. Ipposhi, S. Maegawa, K. Dosaka, and K. Arimoto: “Capacitorless Twin-Transistor Random Access Memory (TTRAM) on SOI,” IEICE Trans. Electron., Vol. E90-c., No. 4 pp. 765-771 (2007)). In such an element, an n+ layer which is to become a source or drain to separate floating body channels of the two MOS transistors is formed in contact with an insulating layer located on the side of a substrate. In the memory cell again, positive hole groups, which are a signal charge are accumulated in the channel of one MOS transistor, and consequently, a challenge for the memory cell is to correct reductions in an operating margin or correct reductions in data retention characteristics through removal of some positive hole groups, which are a signal charge accumulated in the channel, as with the above-mentioned memory cell made up of a single MOS transistor. The present application relates to a memory device using a semiconductor element that can be made up solely of a MOS transistor without a variable resistance element or a capacitor.

### SUMMARY OF INVENTION

An object of the present invention is to provide a methods for stably writing, erasing, and reading memory information with respect to a dynamic flash memory, which is a memory device.

To solve the above problem, a memory device using a semiconductor element according to the present invention comprises: a substrate; a first semiconductor region placed on the substrate; a first impurity region placed on part of a surface of the first semiconductor region; a second impurity region extending in a vertical direction by being placed in contact with the first impurity region; a second semiconductor region extending in the vertical direction by being placed in contact with the second impurity region; a first insulating layer covering part of the first semiconductor region and part of the second impurity region; a first gate insulating layer covering part of the second semiconductor region; a first gate conductor layer placed in contact with the first insulating layer and the first gate insulating layer; a second insulating layer formed in contact with the first gate conductor layer and the first gate insulating layer; a third semiconductor region placed in contact with the second semiconductor region; a second gate insulating layer partially or entirely covering the third semiconductor region; a second gate conductor layer partially or entirely covering the second gate insulating layer; and a third impurity region and a fourth impurity region connected to opposite ends of the third semiconductor region, wherein a contact area between the second impurity region and the second semiconductor region in planar view is smaller than a maximum cross-sectional area of the second semiconductor region in planar view.

According to a second aspect, in the first aspect described above, majority carriers in the first impurity region are different form majority carriers in the first semiconductor region. According to a third aspect, in the first aspect described above, majority carriers in the second impurity region are same as majority carriers in the first impurity region; and majority carriers in the second impurity region are different form majority carriers in the first semiconductor region.

According to a fourth aspect, in the first aspect described above, majority carriers in the second semiconductor region are same as majority carriers in the first semiconductor region.

According to a fifth aspect, in the first aspect described above, majority carriers in the third impurity region and the fourth impurity region are same as majority carriers in the first impurity region.

According to a sixth aspect, in the first aspect described above, the second impurity region is lower in concentration than the third impurity region and the fourth impurity region.

According to a seventh aspect, in the first aspect, a vertical distance from a bottom of the third semiconductor region to an upper part of the second impurity region is shorter than a vertical distance from the bottom of the third semiconductor region to a bottom of the first gate conductor layer.

According to an eighth aspect, in the first aspect, in the vertical direction, a bottom of the first impurity region is located at a lower position than a bottom of the first insulating layer.

According to a ninth aspect, in the first aspect, in the vertical direction, an upper surface of the second impurity region is located at a higher position than an upper surface of the first insulating layer.

According to a tenth aspect, in the first aspect, the first impurity region is shared by a plurality of adjacent memory cells.

According to an eleventh aspect, in the first aspect, a threshold of a MOS transistor made up of the third semiconductor region, the second impurity region, the third impurity region, the second gate insulating layer, and the second gate conductor layer is manipulated by changing a voltage applied to the first gate conductor layer.

According to a twelfth aspect, the first aspect further comprises a fifth impurity region between the second semiconductor region and the third impurity region or a sixth impurity region between the third semiconductor region and the fourth impurity region, wherein a contact area between the second semiconductor region and the fifth impurity region or between the second semiconductor region and the sixth impurity region is smaller than a cross-sectional area of the third impurity region or the fourth impurity region in the vertical direction.

According to a thirteenth aspect, the first aspect further comprises: a first interconnecting conductor layer connected to the third impurity region; a second interconnecting conductor layer connected to the fourth impurity region; a third interconnecting conductor layer connected to the second gate conductor layer; a fourth interconnecting conductor layer connected to the first gate conductor layer; and a fifth interconnecting conductor layer connected to the first impurity region, wherein a memory write operation is performed by controlling voltages applied to the first interconnecting conductor layer, the second interconnecting conductor layer, the third interconnecting conductor layer, the fourth interconnecting conductor layer, and the fifth interconnecting conductor layer, and performing an operation of generating electron groups and positive hole groups in the third semiconductor region and the second semiconductor region by an impact ionization phenomenon or a gate induced drain leakage current using a current passed between the third impurity region and the fourth impurity region, an operation of removing the generated electron groups or positive hole groups whichever are minority carriers in the third semiconductor region and the second semiconductor region, and an operation of causing part or all of majority carriers in the third semiconductor region and the second semiconductor region to remain in the third semiconductor region and the second semiconductor region, and a memory erase operation is performed by controlling voltages applied to the first interconnecting conductor layer, the second interconnecting conductor layer, the third interconnecting conductor layer, the fourth interconnecting conductor layer, and the fifth interconnecting conductor layer and extracting majority carriers remaining in the second semiconductor region or the third semiconductor region from at least one of the first impurity region, the second impurity region, the third impurity region, and the fourth impurity region by recombining the majority carriers with majority carriers in the first impurity region, the second impurity region, the third impurity region, and the fourth impurity region.

According to a fourteenth aspect, in the thirteenth aspect, the first interconnecting conductor layer connected to the third impurity region is a source line, the second interconnecting conductor layer connected to the fourth impurity region is a bit line, the third interconnecting conductor layer connected to the second gate conductor layer is a word line, the fourth interconnecting conductor layer connected to the first gate conductor layer is a plate line, and the fifth interconnecting conductor layer is a control line; and the memory write operation and the memory erase operation are performed by applying voltages to the source line, the bit line, the plate line, the word line, and the control line, respectively.

According to a fifteenth aspect, in the first aspect, during the memory write operation, voltages are applied such that a potential difference is produced between the third impurity region and the fourth impurity region; a positive voltage is applied to the second gate conductor layer when majority carriers in the second semiconductor layer are positive holes and a negative voltage is applied to the second gate conductor layer when majority carriers in the second semiconductor layer are electrons; and a positive voltage or a voltage of 0 volts is applied to the first gate conductor layer.

According to a sixteenth aspect, in the first aspect, during the memory erase operation, a voltage of a different polarity from during the memory write operation or a voltage of 0 volts is applied to the first gate conductor layer.

According to a seventeenth aspect, in the first aspect, during a memory read operation, a voltage of a same polarity as during the memory write operation or a voltage of 0 volts is applied to the first gate conductor layer such that a potential difference is produced between the third impurity region and the fourth impurity region, and a voltage of a same polarity as during the memory write operation is applied to the second gate conductor layer.

According to an eighteenth aspect, in the first aspect, during a memory wait operation, a voltage of a different polarity from a voltage applied during the memory write operation, or a voltage of 0 volts is applied to the first gate conductor layer and the second gate conductor layer.

### BRIEF DESCRIPTION OF THE DRAWINGS

FIG. 1A is a diagram showing a sectional structure of a memory device using a semiconductor element according to a first embodiment and FIG. 1B is a bird's-eye view of the memory device;

FIGS. 2A, 2B and 2C are diagrams for explaining accumulation of positive hole carriers and a cell current during a write operation of the memory device using the semiconductor element according to the first embodiment;

FIGS. 3A, 3B and 3C are diagrams for explaining an erase operation of the memory device using the semiconductor element according to the first embodiment;

FIGS. 4A and 4B are sectional structures of additional example 1 of the memory device using the semiconductor element according to the first embodiment; and

FIGS. 5A and 5B are sectional structures of additional example 2 of the memory device using the semiconductor element according to the first embodiment.

### DETAILED DESCRIPTION OF THE PREFERRED EMBODIMENT

A structure, a drive system, and accumulated-carriers' behavior of a memory device, which uses a semiconductor element, according to an embodiment of the present invention will be described below with reference to the drawings.

### First Embodiment

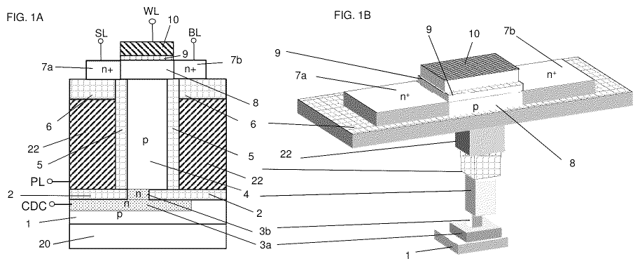

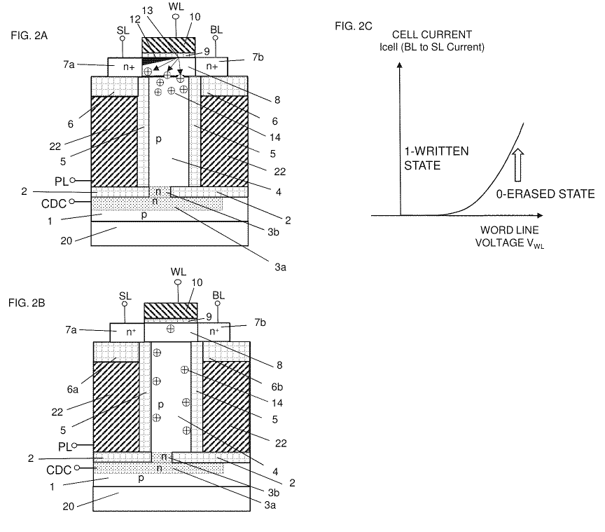

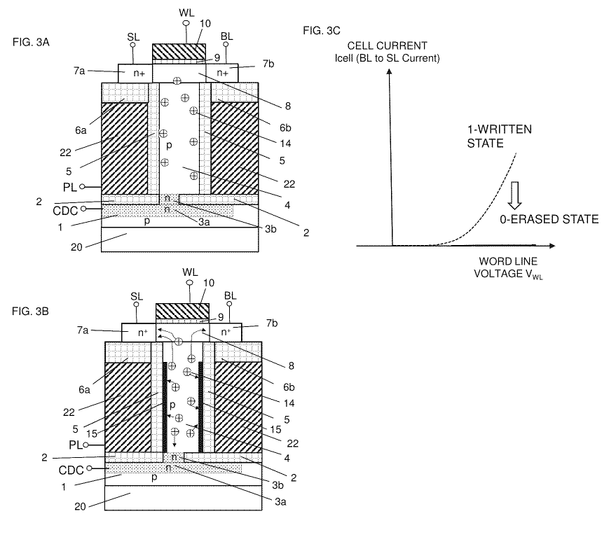

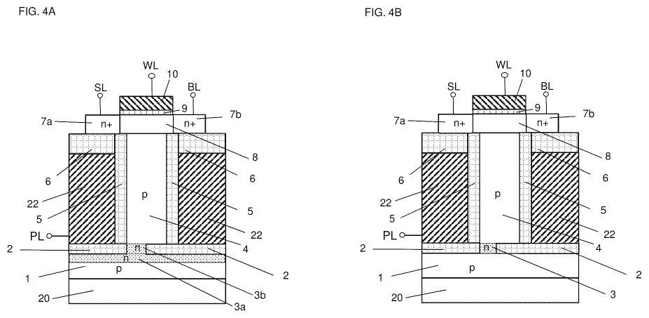

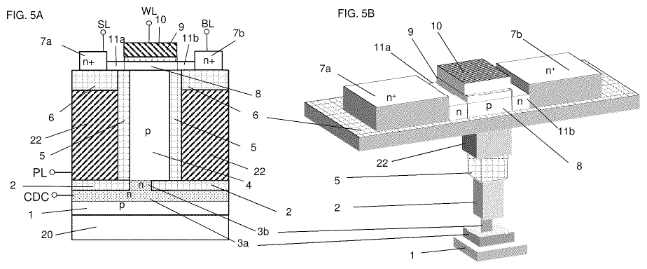

A cell structure and operation of a memory, which uses a semiconductor element, according to the present embodiment will be described using FIGS. 1 to 5. The cell structure of the memory, which uses the semiconductor element, according to the present embodiment will be described with reference to FIGS. 1A and 1B. A write mechanism and carrier behavior of the memory cell using the semiconductor element will be described with reference to FIGS. 2A to 2C. Operation waveforms applied during a memory write operation will be described with reference to FIGS. 3A to 3C. Application example 1 of the present embodiment will be described with reference to FIGS. 4A and 4B. Application example 2 of the present embodiment will be described with reference to FIGS. 5A and 5B.

A vertical sectional structure of the memory using the semiconductor element according to the present embodiment is shown in FIG. 1A. A silicon p-layer 1 (which is an example of a “first semiconductor region” described in Claims) containing acceptor impurities and having a p conductivity type is placed on a substrate 20 (which is an example of a “substrate” described in Claims). A semiconductor having an n-layer 3a (which is an example of a “first impurity region” described in Claims) containing donor impurities is placed in contact with the p-layer 1. In contact with part of the n-layer 3a, a columnar n-layer 3b (which is an example of a “second impurity region” described in Claims) containing donor impurities is erected in a vertical direction. A columnar p-layer 4 (which is an example of a “second semiconductor region” described in Claims) rectangular in a horizontal section and containing acceptor impurities is placed in contact with the n-layer 3b, a maximum cross-sectional area of the p-layer 4 in planar view being larger than a contact area with the n-layer 3b. There is a first insulating layer 2 (which is an example of a “first insulating layer” described in Claims) covering part of the p-layer 1, n-layer 3a, n-layer 3b, and p-layer 4. A first gate insulating layer 5 (which is an example of a “first gate insulating layer” described in Claims) is placed in contact with the first insulating layer 2, covering part of the p-layer 4. Besides, a first gate conductor layer 22 (which is an example of a “first gate conductor layer” described in Claims) is placed in contact with the first insulating layer 2 and the first gate insulating layer 5. A second insulating layer 6 (which is an example of a “second insulating layer” described in Claims) is placed in contact with the gate insulating layer 5 and the gate conductor layer 22. A p-layer 8 (which is an example of a “third semiconductor region” described in Claims) containing acceptor impurities is placed in contact with the p-layer 4.

An n+ layer 7a (which is an example of a “third impurity region” described in Claims) and n+ layer 7b (which is an example of a “fourth impurity region” described in Claims) containing donor impurities are placed in contact with opposite sides of the p-layer 8 in a horizontal direction (hereinafter a semiconductor region containing a high concentration of donor impurities will be referred to as an “n+ layer”).

A second gate insulating layer 9 (which is an example of a “second gate insulating layer” described in Claims) is placed on an upper surface of the p-layer 8. The gate insulating layer 9 is placed in contact with or in proximity to the n+ layers 7a and 7b. In the vertical direction, a second gate conductor layer 10 (which is an example of a “second gate conductor layer” described in Claims) is placed on the gate insulating layer 9.

FIG. 1B shows a bird's-eye view of the memory cell structure according to the present embodiment. In FIG. 1B, for ease of understanding, the p-layer 1, the n-layer 3a, the n-layer 3b, the p-layer 4, the n+ layer 7a, the n+ layer 7b, the p-layer 8, the first gate insulating layer 5, the first gate conductor layer 22, the second gate insulating layer 9, and the second gate conductor layer 10 are shown after removing part of the gate conductor layer 22 and the first insulating layer 2. Note that the second gate insulating layer 9 and the second gate conductor layer 10 are illustrated by being shifted slightly from the p-layer 8 for ease of understanding. A contact area between the n-layer 3b and the p-layer 4 is smaller than a cross-sectional area of the p-layer 4.

This results in formation of the memory device using a semiconductor element made up of the substrate 20, the p-layer 1, the insulating layer 2, the first gate insulating layer 5, the first gate conductor layer 22, the second insulating layer 6, the n-layer 3a, the n-layer 3b, the p-layer 4, the n+ layer 7a, the n+ layer 7b, the p-layer 8, the second gate insulating layer 9, and the second gate conductor layer 10. The n+ layer 7a is connected to a source line SL (which is an example of a “source line” described in Claims), which is a first interconnecting conductive layer, the n+ layer 7b is connected to a bit line BL (which is an example of a “bit line” described in Claims), which is a second interconnecting conductive layer, the gate conductor layer 10 is connected to a word line WL (which is an example of a “word line” described in Claims), which is a third interconnecting conductive layer, the gate conductor layer 22 is connected to a plate line PL (which is an example of a “plate line” described in Claims), which is a fourth interconnecting conductive layer, and the n-layer 3a is connected to a control line CDC (which is an example of a “control line” described in Claims), which is a fifth interconnecting conductive layer. By manipulating voltages applied to the source line SL, the bit line BL, the plate line PL, the word line WL, and the control line CDC, the memory is operated. Hereinafter the memory device will be referred to as a dynamic flash memory.

In the actual memory device according to the present embodiment, a dynamic flash memory cell is placed alone on the substrate 20 or a plurality of the dynamic flash memory cells are placed two-dimensionally on the substrate 20.

Whereas the p-layer 1 is described as being a p-type semiconductor in FIGS. 1A and 1B, impurities may have concentration profiles. The impurity concentrations in the n-layer 3a, the n-layer 3b, the p-layer 4, and the p-layer 8 may also have profiles. The impurity concentrations and profiles in the p-layer 4 and the p-layer 8 may be set independently. The p-layer 4 and the p-layer 8 may be formed of different semiconductor material layers. Cross-sections of the p-layer 4 may have the same shape as a bonding face of the p-layer 4 and the p-layer 8 in planar view. Alternatively, in a direction leading to the n+ layers 7a and 7b, a horizontal length of the p-layer 8 may be either longer or shorter than a width of the p-layer 4. Besides, an LDD (lightly doped drain) region lower in donor impurity concentration than the n+ layers 7a and 7b may be provided between the p-layer 8 and the n+ layers 7a and 7b.

Whereas in FIGS. 1A and 1B, the first semiconductor region 1 has been described as being a p-type semiconductor, even if an n-type semiconductor substrate is used as the substrate 20 and a p-well is formed thereon and the memory cell of the present invention is placed using the p-well as the first semiconductor region 1, the memory cell will operate as a dynamic flash memory.

Whereas the n-layer 3a and the n-layer 3b are shown separately in FIGS. 1A and 1B, the n-layer 3a and the n-layer 3b may be a continuous semiconductor region. Even though a boundary line between the n-layer 3a and the n-layer 3b is illustrated as coinciding with a bottom of the insulating layer 2 in FIGS. 1A and 1B, the boundary line does not necessarily have to coincide with the bottom of the insulating layer 2 as long as the top of the n-layer 3a is located at a level higher than a bottom of the gate conductor layer 22 and the top of the n-layer 3b is located at a level equal to or higher than the bottom of the gate conductor layer 22 in the vertical direction. In FIGS. 1A and 1B, there is no need to form the n-layer 3a on the entire surface as long as the n-layer 3a exists under the memory cell. Furthermore, the n-layer 3a may be formed by an n-well in the p-layer 1. Note that hereinafter the n-layer 3a and the n-layer 3b may be collectively referred to as the n-layers 3.

Whereas the insulating layer 2 and the gate insulating layer 5 are shown separately in FIGS. 1A and 1B, the insulating layer 2 and the gate insulating layer 5 may be formed integrally. Hereinafter the insulating layer 2 and the gate insulating layer 5 will also be together referred to as the gate insulating layer 5.

Whereas the p-layer 8 is a p-type semiconductor in FIGS. 1A and 1B, the p-layer 8 may be any of the p-type, n-type, and i-type depending on the majority carrier concentration of the p-layer 4, the thickness of the p-layer 8, the material and thickness of the gate insulating layer 9, and the material of the gate conductor layer 10.

The substrate 20 may be made of any material such as an insulator, a semiconductor, or a conductor as long as the material can support the p-layer 1.

The first to fifth interconnecting conductive layers may be multi-layered as long as the layers do not contact one another.

The gate insulating layers 5 and 9 may be made of any insulating film used in a normal MOS process, such as a SiO2 film, a SiON film, a HfSiON film, or a SiO2/SiN laminate film.

The first gate conductor layer 22 may be formed, for example, of a metal such as W, Pd, Ru, Al, TiN, TaN, or WN; a nitride of the metal; an alloy thereof (including silicides); a laminated structure such as TiN/W/TaN; or a semiconductor doped at high concentration as long as a potential of part of the memory cell can be changed via the gate insulating layer 5, the second gate conductor layer 10, or the gate insulating layer 9.

Regarding the memory cell, the vertical sectional structure of the p-layer 4 and the p-layer 8 has been described as being rectangular in FIGS. 1A and 1B, but may be trapezoidal or polygonal. Besides, the cross-sectional shape of the p-layer 4 may be circular or elliptical in planar view.

The MOSFET made up of the n+ layers 7a and 7b, the p-layer 8, the gate insulating layer 9, and the gate conductor layer 10 may be a planar MOSFET or a Fin FET.

In the case of a planar type, the second gate insulating layer 9 is formed on an upper surface of the p-layer 8, and the second gate conductor layer 10 is formed on the gate insulating layer. In the case of a Fin type, the second gate insulating layer 9 is formed on the upper surface of the p-layer 8 and on two opposing side faces, and the second gate conductor layer 10 is formed covering the gate insulating layer. Alternatively, the MOSFET may be an FET, the p-layer 8 of which, which is a channel, is U-shaped.

In FIGS. 1A and 1B, the first gate conductor layer 22 may surround the entire first gate insulating layer 5 or cover part of the first gate insulating layer 5 in planar view. The first gate conductor layer 22 may be divided into multiple parts in planar view. The first gate conductor layer 22 may be divided into multiple parts in the vertical direction. Whereas in sectional structure, the first gate conductor layers 22 exist on opposite sides of the p-layer 4 in FIGS. 1A and 1B, the dynamic flash memory can operate if the first gate conductor layer 22 exists on either side of the p-layer 4.

When p+ layers (hereinafter a semiconductor region containing a high concentration of acceptor impurities will be referred to as a “p+ layer”) in which positive holes act as majority carriers are formed in place of the n+ layer 7a and the n+ layer 7b, if n-type semiconductors are used for the p-layer 1, the p-layer 4, and the p-layer 8 and p-type semiconductors are used for the n-layer 3a and the n-layer 3b, the dynamic flash memory can operate with electrons serving as carriers during writing.

Carrier behavior and accumulation as well as a cell current during a write operation (which is an example of a “write operation” described in Claims) of the dynamic flash memory according to the first embodiment of the present invention will be described with reference to FIGS. 2A to 2C. First, description will be given of a case in which the majority carriers in the n-layer 3a, the n-layer 3b, the n+ layer 7a, and the n+ layer 7b are electrons, poly Si containing a high concentration of donor impurities (hereinafter poly Si containing a high concentration of donor impurities will be referred to as “n+poly”) is used, for example, for the gate conductor layer 22 connected to the plate line PL and the gate conductor layer 10 connected to the word line WL, and a p-type semiconductor is used as a third semiconductor region 8. As shown in FIG. 2A, a MOSFET in the memory cell operates using the following components: the n+layer 7a that serves as a source, the n+ layer 7b that serves as a drain, the gate insulating layer 9, the gate conductor layer 10 that serves as a gate, and the p-layer 8 that serves as a substrate. For example, 0 V is applied to the p-layer 1, 0.5 V is applied to the n-layer 3a connected with the control line CDC, 0 V is input to the n+ layer 7a connected with the source line SL, 1.0 V is input to the n+ layer 7b connected with the bit line BL, and −1 V is applied to the gate conductor layer 22 connected with the plate line PL. It is assumed here that a threshold of a MOSFET that uses the pre-writing gate conductor layer 10 as a gate electrode is, for example, 1.0 V when the voltage of the plate line PL is −1 V. Next, if, for example, 1.5 V is input to the gate conductor layer 10 connected with the word line WL, an inversion layer 12 is formed partially just under the gate insulating layer 9 located below the gate conductor layer 10 with a pinch-off point 13 existing in the inversion layer 12. Therefore, the MOSFET having the gate conductor layer 10 operates in a saturation region.

As a result, in the MOSFET having the gate conductor layer 10, an electric field is maximized in a region between the pinch-off point 13 and the n+ layer 7b and an impact ionization phenomenon occurs in this region. As a result of the impact ionization phenomenon, electrons accelerated in a direction from the n+ layer 7a connected with the source line SL to the n+ layer 7b connected with the bit line BL collide with a Si lattice and electron-hole pairs are generated by kinetic energy of the accelerated electrons. Due to a concentration gradient, the generated positive holes diffuse in a direction in which a hole concentration is lower. Part of the generated electrons flow to the gate conductor layer 10, but the majority of the electrons flow to the n+ layer 7b connected to the bit line BL. As a result, positive hole groups 14 are accumulated in the p-layer 4 and the p-layer 8.

In the above example, the plate line PL is set at −1 V, and this contributes to preventing a depletion layer from spreading in the p-layer and thereby accumulating positive holes generated by impact ionization as well as to adjusting a threshold voltage of the MOSFET in the memory cell by means of a substrate bias effect.

In the above example, the gate conductor layer 22 is biased with a negative voltage using n+poly, but an effect similar to application of a negative voltage can be obtained using a material higher in work function than the material of the gate conductor layer 10.

Note that positive hole groups may be generated by passing a gate induced drain leakage (GIDL) current instead of causing the impact ionization phenomenon (see, for example, J. Wan, L. Rojer, A. Zaslavsky, and S. Critoloveanu: “A Compact Capacitor-Less High-Speed DRAM Using Field Effect-Controlled Charge Regeneration,” Electron Device Letters, Vol. 35, No. 2, pp. 179-181 (2012)).

FIG. 2B shows positive hole groups 14 existing in the p-layer 4 and the p-layer 8 when the plate line PL becomes −1 V, biases to the word line WL, the source line SL, and the bit line BL become 0 V, and a bias to the control line CDC becomes 0.5 V just after writing. The generated positive hole groups 14 are majority carriers in the p-layer 4 and the p-layer 8, but the resulting hole concentration becomes temporarily high in a region of the p-layer 8. Due to the concentration gradient, the positive hole groups move toward the p-layer 4 through diffusion. Furthermore, because a negative potential is applied to the first gate conductor layer 22, the positive hole groups are accumulated in higher concentrations in the vicinity of the first gate insulating layer 5 of the p-layer 4. Since the p-layer 4 and the p-layer 8 are electrically connected, the p-layer 8, which is a MOSFET substrate that practically has the gate conductor layer 10, is charged to be positively biased. The threshold voltage of the MOSFET containing the gate conductor layer 10 is reduced due to a positive substrate bias effect produced by the positive holes temporarily accumulated in the p-layer 4 and the p-layer 8. In the present example, the threshold voltage of the MOSFET after writing becomes 0.6 V. Consequently, as shown in FIG. 2C, the threshold voltage of the MOSFET containing the gate conductor layer 10 connected with the word line WL, becomes approximately 0.3 V, which is lower than the pre-writing threshold voltage. This written state is assigned to logical storage data “1.”

With the structure according to the present embodiment, since the p-layer 8 of the MOSFET containing the gate conductor layer 10 connected with the word line WL is electrically connected to the p-layer 4, the capacity capable of accumulating generated positive holes can be changed freely by the volume of the p-layer 4. Furthermore, areas placed in contact with the n-layer 3b, the n+ layer 7a, and the n+ layer 7b involved in recombination with electrons can be reduced intentionally compared to the volumes of the p-layer 4 and the p-layer 8 in which positive hole carriers are accumulated. In particular, because a contact area between the p-layer 4 and the n-layer 3b is smaller than a maximum horizontal cross-sectional area of the p-layer 4, chances of recombination between positive holes and electrons accumulated after a write operation are reduced further and retention time can be increased.

In addition to the above example, if the voltages applied to the bit line BL, the plate line PL, and the word line WL are abbreviated, for example, to V-BL, V-PL, and V-WL; assuming that SL is 0 V, voltage application conditions may be a combination of 1.0 V (V-BL)/-1 V (V-PL)/2.0 V (V-WL), 1.0 V (V-BL)/-0.5 V (V-PL)/1.2 V (V-WL), 1.5 V (V-BL)/-1 V (V-PL)/2.0 V (V-WL), or the like. The voltage relationship between the bit line BL and the source line SL may be exchanged. However, if 1.0 V is applied to the bit line BL, 0 V to the source line SL, 2 V to the word line WL, and −1 V to the plate line PL, the threshold will fall during writing, causing the pinch-off point 13 to shift gradually toward the n+ layer 7b, and consequently, the MOSFET may perform a linear operation.

Next, a mechanism of an erase operation (which is an example of an “erase operation” described in Claims) will be described using FIGS. 3A to 3C. FIG. 3A shows a state just after the positive hole groups 14 generated by impact ionization in the previous cycle are stored in the p-layer 4 and the p-layer 8 before the erase operation. The voltages of the source line SL, the bit line BL, and the control line CDC are 0.5 V while the voltages of the word line WL and the plate line PL are −1 V.

As shown in FIG. 3B, during the erase operation, the voltages of the source line SL, the bit line BL, and the word line WL are set to 0 V and the voltage of the control line CDC is set to 0.5 V. The voltage of the plate line PL is set, for example, to 2 V. As a result, regardless of the value of an initial potential of the p-layer 8, an inversion layer 15 of electrons is formed in an interface between the insulating layer 5 and the p-layer 4. Part of the inversion layer 15 is placed in contact with the n-layer 3b. Consequently, positive holes accumulated in the p-layer 4 flow from the p-layer 4 to the inversion layer 15 and recombine with electrons. The electrons lost as a result of the recombination are furnished from the inversion layer 15 in contact with the p-layer 4, through the n-layer 3a and the n-layer 3b. The inversion layer 15 is illustrated in FIG. 3B as being parted right and left, but the right and left parts, which are formed around the p-layer 4, are electrically connected and the reduction in the contact area between the p-layer 4 and the n-layer 3b has no impact. As a result of the recombination between the electrons and the positive holes, the hole concentrations of the p-layer 4 and the p-layer 8 are reduced with time, and the threshold voltage of the MOSFET becomes higher than when “1” is written. Here, for example, if the voltage of the plate line PL is −1 V, the threshold of the MOSFET becomes 1.2 V. Consequently, as shown in FIG. 3C, the MOSFET containing the gate conductor layer 10 connected with the word line WL returns to the original threshold. The erased state of the dynamic flash memory becomes “0” in terms of logical storage data.

With the structure according to the present embodiment, during data erasure, compared to during data accumulation, an electron-hole recombination area can be effectively increased. Therefore, logic information data of “0” can be put into a stable state in a short time, improving the operating speed of the dynamic flash memory element. Besides, power consumed for data erasure is approximately equal to the total quantity of holes accumulated in the p-layer 4 and the p-layer 8. Because no other current flows, power consumption can be reduced greatly.

In data erase methods other than the one taken as an example, if the voltages applied to the bit line BL, the plate line PL, and the word line WL are abbreviated, for example, to V-BL, V-PL, and V-WL; assuming that SL is 0 V and the control line CDC is 0.5 V, voltage application conditions may be a combination of 0 V (V-BL)/2 V (W-PL)/-1 V (V-WL), 0.4 V (V-BL)/2 V (V-PL)/0.5 V (V-WL), 1 V (V-BL)/1.5 V (V-L)/0 V (V-WL), or the like. The conditions of the voltages applied to the bit line BL, the source line SL, the word line WL, and the plate line PL are only an example used in performing a memory erase operation, and other operating conditions that allow memory erase operations to be performed may be used.

The insulating layer 2, the insulating layer 6, and the gate insulating layer 5 can be formed simultaneously and can be formed of the same material as well. Besides, by adjusting the film thickness of each of the gate insulating layer 5 and insulating layers 2 and 6, the voltage applied to the gate conductor layer 22 can be adjusted.

Whereas the control line CDC has been described as being at 0.5 V during both memory writing and erasure, the control line CDC may be set to the ground voltage, i.e., to 0 V.

The memory enters a wait operation (which is an example of a “memory wait operation” described in Claims) after a write operation or an erase operation, and in this case, voltages of a different polarity from voltages applied during the write operation, or a voltage of 0 V is applied to the gate conductor layer 22 connected with the plate line and the gate conductor layer 10 connected with the word line. The impurity layer 7a connected with the source line SL and the impurity layer 7b connected with the bit line BL are at 0 V.

According to the present embodiment, the p-layer 8, which is one of the components of the MOSFET that reads and writes information, is electrically connected with the p-layer 1, the n-layer 3, and the p-layer 4. Furthermore, a voltage can be applied to the gate conductor layer 22 and potential of the p-layer 4 can be controlled by humans. Therefore, both in the write operation and the erase operation, unlike, for example, an SOI structure, neither the substrate bias becomes unstable in a floating state during operation of the MOSFET nor a semiconductor portion under the gate insulating layer 9 becomes completely depleted. Consequently, the threshold, a drive current, and the like of the MOSFET are not easily affected by operational status.

The present embodiment is effective in preventing malfunctions of memory cells. In memory cell operation, when voltages of a target cell are manipulated, unnecessary voltages are applied to some electrodes of cells other than the target cell in a cell array, resulting in a malfunction, which presents a big problem (for example, T. Shino, N. Kusunoki, T. Higashi, T. Ohsawa, K. Fujita, K. Hatsuda, N. Ikumi, F. Matsuoka, Y. Kajitani, R. Fukuda, Y. Watanabe, Y. Minami, A. Sakamoto, J. Nishimura, H. Nakajima, M. Morikado, K. Inoh, T. Hamamoto, A. Nitayama: “Floating Body RAM Technology and its Scalability to 32 nm Node and Beyond,” IEEE IEDM (2006)). Specifically, such a malfunction involves a phenomenon in which logic “1” data written into a memory cell is turned to logic “0” data by another memory cell operation or logic “0” data written into a cell is turned to logic “1” data by other cell operations (hereinafter the phenomenon caused by such a malfunction will be referred to as a “disturbance failure”). According to the present embodiment, when “1” is originally written as data information, accumulated positive holes minimize a contact area between the n-layers 3 and the p-layer 4, reducing the quantity of electron-hole recombination, and even under conditions in which conventional memories cause a disturbance failure, threshold fluctuations of the MOSFET are not affected much, and thus the MOSFET is less prone to failure. On the other hand, when “0” is originally written as data information, even if unintended positive holes are generated by transistor operation during reading, because the positive holes diffuse quickly in the p-layer 4, if the depth of the p-layer 4 is increased similarly, a rate of change of hole concentration in the entire p-layer 4 and p-layer 8 is low and again, the threshold of the MOSFET is not affected much, and the probability of occurrence of disturbance failure can be reduced more than before. Thus, the present embodiment provides a structure resistant to disturbance failure of memory.

According to the present embodiment, because memory can also be erased by applying a positive voltage to the plate line PL at the time of erasure, information in a plurality of cells sharing the gate conductor layer 22 can be erased at once.

As can be seen from the structure shown in FIGS. 1A and 1B, an element structure made up of the p-layer 8, the n+ layers 7a and 7b, the gate insulating layer 9, and the gate conductor layer 10 can be formed not only of the present memory cell, but also in common with a MOS circuit containing a typical CMOS structure other than the present structure. For example, the p-layer 1, the p-layer 4, and the p-layer 8 can be shared as part of the CMOS structure. Thus, the present memory cell can be easily combined with conventional CMOS circuits.

Because the memory cell of the present invention is formed in the area of one MOSFET in planar view, by sharing the source line and the bit line with adjacent memory cells, a higher-density memory cell array than conventional dynamic RAMs can be implemented.

An additional example of the dynamic flash memory according to the present invention will be described using FIGS. 4A and 4B. In FIGS. 4A and 4B, same or similar components as/to those shown in FIGS. 1A and 1B are denoted by reference signs containing the same numerical symbols as the corresponding components in FIGS. 1A and 1B.

As shown in FIG. 4A, the bottoms of the n-layers 3 in FIGS. 1A and 1B are located shallower than the gate insulating layer 2, and no control line CDC exists. Otherwise, FIG. 4A is the same as FIGS. 1A and 1B.

As shown in FIG. 4B, even if each memory cell has an individual n-layer 3 placed on the bottom of the p-layer 4 rather than the n-layer 3 is shared by a plurality of cells, the dynamic flash memory can also operate.

With either of the structures in FIGS. 4A and 4B, by the application of voltages similar to the first embodiment to the source line SL, the plate line PL, the word line WL, and the bit line BL, excluding the control line CDC, the write operation, the erase operation, and the read operation of the dynamic flash memory can be performed.

One of the interconnect structures becomes unnecessary compared to FIGS. 1A and 1B and operation needs slight adjustments, but processes become simpler and easier from the viewpoint of manufacturing.

Another additional example of the dynamic flash memory according to the present invention will be described using FIGS. 5A and 5B. In FIGS. 5A and 5B, same or similar components as/to those shown in FIGS. 1A and 1B are denoted by reference signs containing the same numerical symbols as the corresponding components in FIGS. 1A and 1B.

According to the embodiment shown in FIGS. 1A and 1B, in the source and the drain area of the MOSFET, a contact area between the p-layer 8 and n+ layer 7a or 7b forming a p-n junction is almost equal to the cross-sectional area of the n+ layers 7a and 7b in the vertical direction. In contrast, in FIGS. 5A and 5B, the p-layer 8 is made thinner and an n-layer 11a (which is an example of a “fifth impurity region” described in Claims) and an n-layer 11b (which is an example of a “sixth impurity region” described in Claims), both of which are thinner than the n+ layers 7a and 7b, are inserted between the p-layer 8 and the n+ layers 7a and 7b. Compared with FIGS. 1A and 1B, this structure can further reduce a total p-n junction area in the memory cell, and thus curb electron-hole recombination accumulated during memory writing and further increase the retention time of accumulated positive holes.

Whereas the present embodiment has been described by taking as an example a case in which the p-layers 4 and 8 are formed vertically with respect to the substrate 20, the present invention is also applicable when the p-layers 4 and 8 are formed in a horizontal direction.

The present embodiment has the following features.

### (Feature 1)

In the dynamic flash memory according to the first embodiment of the present invention, a substrate area on which a MOSFET channel is formed is made up of the p-layer 4 and the p-layer 8 surrounded by the insulating layer 2, the gate insulating layer 5, the n-layers 3, and the n+ layers 7a and 7b. By reducing the area of the p-n junction formed in contact with the p-layer 4, the p-layer 8, the n-layers 3, and the n+ layers 7a and 7b, it is possible to minimize the recombination area of accumulated positive holes and electrons and thereby extend the information retention time of the positive holes. Furthermore, because the positive holes generated during writing by the application of a negative voltage to the gate conductor layer 22 can be accumulated near the interface of the p-layer 4 in the vicinity of the gate conductor layer 22 and no depletion layer is formed in the p-layer 4, the accumulated quantity of positive holes can be increased and information retention time is extended.

During data erasure, as an inversion layer and a depletion layer are formed by the application of a positive voltage to the gate conductor layer 22, effectively increasing the electron-hole recombination area, the recombination area with electrons can be increased and the erasure is done in a short time. This makes it possible to expand the operating margin of the memory and reduce power consumption, resulting in high-speed action of the memory.

### (Feature 2)

The p-layer 8, which is a component of the MOSFET contained in the dynamic flash memory according to the first embodiment of the present invention, is connected with the p-layer 4, the n-layers 3a and 3b, and the p-layer 1, and if the voltage applied to the gate conductor layer 22 is adjusted, the p-layer 8 and the p-layer 4 under the gate insulating layer 9 are not completely depleted and the threshold of the MOSFET can be set freely. Consequently, the threshold, drive current, and the like of the MOSFET are not easily affected by the operational status of the memory. Furthermore, since the components under the MOSFET are not completely depleted, coupling of a word line in a floating state to a gate electrode, which is a defect of capacitorless DRAMs, almost does not have a significant impact. That is, the present invention allows a wide margin to be provided to the operating voltage of the dynamic flash memory.

### (Feature 3)

The p-layer 8, which is a component of the MOSFET contained in the dynamic flash memory according to the first embodiment of the present invention, is connected with the p-layer 4, the quantity of positive holes accumulated when information data of “1” is written can be made 10 times or more larger than, for example, a conventional zero-capacitor DRAM (M. G. Ertosun, K. Lim, C. Park, J. Oh, P. Kirsch, and K. C. Saraswat: “Novel Capacitorless Single-Transistor Charge-Trap DRAM (1T CT DRAM) Utilizing Electron,” IEEE Electron Device Letter, Vol. 31, No. 5, pp. 405-407 (2010); and T. Shino, N. Kusunoki, T. Higashi, T. Ohsawa, K. Fujita, K. Hatsuda, N. Ikumi, F. Matsuoka, Y. Kajitani, R. Fukuda, Y. Watanabe, Y. Minami, A. Sakamoto, J. Nishimura, H. Nakajima, M. Morikado, K. Inoh, T. Hamamoto, A. Nitayama: “Floating Body RAM Technology and its Scalability to 32 nm Node and Beyond,” IEEE IEDM (2006)). Therefore, even if disturbance factors affect the voltages applied to the memory cell for purposes other than reading and writing, written information data of “1” does not disappear easily. If the p-n junction area existing in the memory cell is reduced, an area in which positive holes and electrons recombine with each other can be reduced. This provides a structure that makes “1” harder to disappear. When information data of “0” is being written into memory, even if disturbance factors affect the voltages applied to the memory cell for purposes other than reading and writing and positive holes other than intended ones are generated in the memory cell, positive holes in quantities large enough to turn the information into “1” in a short time are not generated. Thus, the present invention is a memory cell structure resistant to disturbance failure.

### (Feature 4)

With the dynamic flash memory according to the first embodiment of the present invention, when a plurality of cells are placed in the n-layers 3 and the gate conductor layer 22 is shared, an erase operation can be performed on a plurality of cells in a single procedure.

### (Feature 5)

With the dynamic flash memory according to the first embodiment of the present invention, because the current that flows during data erasure is limited to about the same level as the total quantity of positive holes accumulated in the memory cell, power consumption is very low.

### (Feature 6)

The dynamic flash memory according to the first embodiment of the present invention provides a high-density memory cell array and a CMOS-compatible structure.

### INDUSTRIAL APPLICABILITY

The use of the semiconductor element according to the present invention provides a semiconductor memory device higher in density, speed, and operating margin than conventional semiconductor memory devices.

What is claimed is:

1. A memory device using a semiconductor element, comprising:
a substrate;
a first semiconductor region placed on the substrate;
a first impurity region placed on part of a surface of the first semiconductor region;
a second impurity region extending in a vertical direction by being placed in contact with the first impurity region;
a second semiconductor region extending in the vertical direction by being placed in contact with the second impurity region;
a first insulating layer covering part of the first semiconductor region and part of the second impurity region;
a first gate insulating layer covering part of the second semiconductor region;
a first gate conductor layer placed in contact with the first insulating layer and the first gate insulating layer;
a second insulating layer formed in contact with the first gate conductor layer and the first gate insulating layer;
a third semiconductor region placed in contact with the second semiconductor region;
a second gate insulating layer partially or entirely covering the third semiconductor region;
a second gate conductor layer partially or entirely covering the second gate insulating layer; and
a third impurity region and a fourth impurity region connected to opposite ends of the third semiconductor region, wherein
a contact area between the second impurity region and the second semiconductor region in planar view is smaller than a maximum cross-sectional area of the second semiconductor region in planar view.

2. The memory device using a semiconductor element according to claim 1, wherein majority carriers in the first impurity region are different form majority carriers in the first semiconductor region.

3. The memory device using a semiconductor element according to claim 1, wherein:
majority carriers in the second impurity region are same as majority carriers in the first impurity region; and
majority carriers in the second impurity region are different form majority carriers in the first semiconductor region.

4. The memory device using a semiconductor element according to claim 1, wherein majority carriers in the second semiconductor region are same as majority carriers in the first semiconductor region.

5. The memory device using a semiconductor element according to claim 1, wherein majority carriers in the third impurity region and the fourth impurity region are same as majority carriers in the first impurity region.

6. The memory device using a semiconductor element according to claim 1, wherein the second impurity region is lower in concentration than the third impurity region and the fourth impurity region.

7. The memory device using a semiconductor element according to claim 1, wherein a vertical distance from a bottom of the third semiconductor region to an upper part of the second impurity region is shorter than a vertical distance from the bottom of the third semiconductor region to a bottom of the first gate conductor layer.

8. The memory device using a semiconductor element according to claim 1, wherein in the vertical direction, bottom of the first impurity region is located at a lower position than a bottom of the first insulating layer.

9. The memory device using a semiconductor element according to claim 1, wherein in the vertical direction, an upper surface of the second impurity region is located at a higher position than an upper surface of the first insulating layer.

10. The memory device using a semiconductor element according to claim 1, wherein the first impurity region is shared by a plurality of adjacent memory cells.

11. The memory device using a semiconductor element according to claim 1, wherein a threshold of a MOS transistor made up of the third semiconductor region, the second impurity region, the third impurity region, the second gate insulating layer, and the second gate conductor layer is manipulated by changing a voltage applied to the first gate conductor layer.

12. The memory device using a semiconductor element according to claim 1, further comprising a fifth impurity region between the second semiconductor region and the third impurity region or a sixth impurity region between the third semiconductor region and the fourth impurity region, wherein
a contact area between the second semiconductor region and the fifth impurity region or between the second semiconductor region and the sixth impurity region is smaller than a cross-sectional area of the third impurity region or the fourth impurity region in the vertical direction.

13. The memory device using a semiconductor element according to claim 1, further comprising:
a first interconnecting conductor layer connected to the third impurity region;
a second interconnecting conductor layer connected to the fourth impurity region;
a third interconnecting conductor layer connected to the second gate conductor layer;
a fourth interconnecting conductor layer connected to the first gate conductor layer; and
a fifth interconnecting conductor layer connected to the first impurity region,
wherein a memory write operation is performed by controlling voltages applied to the first interconnecting conductor layer, the second interconnecting conductor layer, the third interconnecting conductor layer, the fourth interconnecting conductor layer, and the fifth interconnecting conductor layer, and performing an operation of generating electron groups and positive hole groups in the third semiconductor region and the second semiconductor region, by an impact ionization phenomenon or a gate induced drain leakage current using a current passed between the third impurity region and the fourth impurity region, an operation of removing the generated electron groups or positive hole groups whichever are minority carriers in the third semiconductor region and the second semiconductor region, and an operation of causing part or all of majority carriers in the third semiconductor region and the second semiconductor region to remain in the third semiconductor region and the second semiconductor region, and
a memory erase operation is performed by controlling voltages applied to the first interconnecting conductor layer, the second interconnecting conductor layer, the third interconnecting conductor layer, the fourth interconnecting conductor layer, and the fifth interconnecting conductor layer and extracting majority carriers remaining in the second semiconductor region or the third semiconductor region from at least one of the first impurity region, the second impurity region, the third impurity region, and the fourth impurity region by recombining the majority carriers with majority carriers in the first impurity region, the second impurity region, the third impurity region, and the fourth impurity region.

14. The memory device using a semiconductor element according to claim 13, wherein:
the first interconnecting conductor layer connected to the third impurity region is a source line, the second interconnecting conductor layer connected to the fourth impurity region is a bit line, the third interconnecting conductor layer connected to the second gate conductor layer is a word line, the fourth interconnecting conductor layer connected to the first gate conductor layer is a plate line, and the fifth interconnecting conductor layer is a control line;
the memory write operation and the memory erase operation are performed by applying voltages to the source line, the bit line, the plate line, the word line, and the control line, respectively.

15. The memory device using a semiconductor element according to claim 1, wherein:
during the memory write operation, voltages are applied such that a potential difference is produced between the third impurity region and the fourth impurity region;
a positive voltage is applied to the second gate conductor layer when majority carriers in the second semiconductor layer are positive holes and a negative voltage is applied to the second gate conductor layer when majority carriers in the second semiconductor layer are electrons; and
a positive voltage or a voltage of 0 V is applied to the first gate conductor layer.

16. The memory device using a semiconductor element according to claim 1, wherein during the memory erase operation, a voltage of a different polarity from during the memory write operation or a voltage of 0 V is applied to the first gate conductor layer.

17. The memory device using a semiconductor element according to claim 1, wherein during a memory read operation, a voltage of a same polarity as during the memory write operation or a voltage of 0 V is applied to the first gate conductor layer such that a potential difference is produced between the third impurity region and the fourth impurity region, and a voltage of a same polarity as during the memory write operation is applied to the second gate conductor layer.

18. The memory device using a semiconductor element according to claim 1, wherein during a memory wait operation, a voltage of a different polarity from a voltage applied during the memory write operation, or a voltage of 0 V is applied to the first gate conductor layer and the second gate conductor layer.
